(19) United States
(12) Patent Application Publication
(10) Pub. No.: US 2017/0178867 A1
(43) Pub. Date: Jun. 22, 2017

(54) GAS DIFFUSER HAVING GROOVED HOLLOW CATHODES

(71) Applicant: Applied Materials, Inc., Santa Clara, CA (US)

(72) Inventors: Jozef KUDELA, Morgan Hill, CA (US); Allen K. LAU, Cupertino, CA (US); Robin L. TINER, Santa Cruz, CA (US); Gaku FURUTA, Sunnyvale, CA (US); John M. WHITE, Hayward, CA (US); William Norman STERLING, Santa Clara, CA (US); Dongsuh LEE, Gilroy, CA (US); Suhail ANWAR, Saratoga, CA (US); Shinichi KURITA, San Jose, CA (US)

(21) Appl. No.: 15/365,497

(22) Filed: Nov. 30, 2016

Related U.S. Application Data
(60) Provisional application No. 62/269,832, filed on Dec. 18, 2015.

(51) Int. Cl. H01J 37/32

(52) U.S. Cl. CPC H01J 37/32449; H01J 37/32082; H01J 37/32532; H01J 2237/3321

(57) ABSTRACT

In one embodiment, a diffuser for a deposition chamber includes a plate having edge regions and a center region, and plurality of gas passages comprising an upstream bore and an orifice hole fluidly coupled to the upstream bore that are formed between an upstream side and a downstream side of the plate, and a plurality of grooves surrounding the gas passages, wherein a depth of the grooves varies from the edge regions to the center region of the plate.

### CROSS-REFERENCE TO RELATED APPLICATIONS

This application claims benefit of U.S. Provisional Patent Application No. 62/269,832 filed Dec. 18, 2015, which is herein incorporated by reference.

### BACKGROUND

Field

Embodiments of the disclosure generally relate to a gas distribution plate or diffuser that may be utilized as a radio frequency electrode, and a method for distributing gas and forming a plasma in a processing chamber.

Description of the Related Art

Liquid crystal displays or flat panel screens are commonly used for active matrix displays such as computer monitors, mobile device screens and television screens. Thin film transistors (TFTs) and active matrix organic light emitting diodes (AMOLEDs) are but two types of devices for forming flat panel screens. Plasma enhanced chemical vapor deposition (PECVD) is generally employed to deposit thin films on a substrate, such as a transparent glass or plastic substrate, for the flat panel screens. PECVD is generally accomplished by introducing a precursor gas or gas mixture into a vacuum chamber that contains a substrate. The precursor gas or gas mixture is typically directed downwardly through a gas diffuser positioned in the chamber. The precursor gas or gas mixture in the chamber is energized (e.g., excited) into a plasma by applying radio frequency (RF) power to the gas diffuser from one or more RF sources coupled to the chamber. The excited gas or gas mixture reacts to form a layer of material on a surface of the substrate that is positioned on a temperature controlled substrate support.

Substrates for flat panel screens processed by PECVD techniques are typically large, often exceeding 4 square meter surface area, and the gas diffusers are sized similar to the surface area of the substrate. Conventional gas diffusers include a plate having thousands of holes formed therethrough to distribute precursor gases or gas mixtures onto the substrate. Each of the holes is typically formed by multiple drilling or milling operations, which is time-consuming. The gas diffusers may also function as an electrode in the formation of a plasma of the precursor gas or gas mixture. However, plasma density across the large surface area of the substrate is difficult to control.

Therefore, there is a need for an improved gas diffuser.

### SUMMARY

The present disclosure generally relates to a gas distribution plate that may be utilized as a radio frequency (RF) electrode designed to ensure substantially uniform deposition of films on a substrate with a plasma. In one embodiment, a diffuser for a deposition chamber is provided. The diffuser includes a plate having edge regions and a center region, and a plurality of gas passages comprising an upstream bore and an orifice hole fluidly coupled to the upstream bore that are formed between an upstream side and a downstream side of the plate, and a plurality of grooves surrounding the gas passages, wherein a depth of the grooves varies from the edge regions to the center region of the plate.

In another embodiment, a diffuser for a deposition chamber is provided. The diffuser includes a plate having edge regions and a center region, and plurality of gas passages comprising an upstream bore and an orifice hole fluidly coupled to the upstream bore that are formed between an upstream side and a downstream side of the plate, and a plurality of hollow cathode cavities surrounding the gas passages, wherein each of the hollow cathode cavities comprise a groove and a depth of the grooves increases from the center region to the edge regions of the plate.

In another embodiment, a diffuser for a deposition chamber is provided. The diffuser includes a plate having edge regions and a center region, and plurality of gas passages comprising an upstream bore and an orifice hole fluidly coupled to the upstream bore that are formed between an upstream side and a downstream side of the plate, and a plurality of hollow cathode cavities formed in a groove pattern on a downstream side of the plate and surrounding the gas passages, wherein the groove pattern comprises a plurality of grooves having a depth that increases from the center region to the edge regions of the plate.

In another embodiment, an electrode for a deposition chamber is provided. The electrode includes a plate having edge regions and a center region, and plurality of gas passages comprising an upstream bore and an orifice hole fluidly coupled to the upstream bore that are formed between an upstream side and a downstream side of the plate, and a plurality of hollow cathode cavities formed in a groove pattern on a downstream side of the plate and surrounding the gas passages, wherein the groove pattern comprises a plurality of grooves having a size that varies from the center region to the edge regions of the plate

In another embodiment, a method of processing a substrate on a substrate support is provided. The method includes delivering a deposition gas through a diffuser. The diffuser comprises a plate having edge regions and a center region, and plurality of gas passages comprising an upstream bore and an orifice hole fluidly coupled to the upstream bore that are formed between an upstream side and a downstream side of the plate, and a plurality of hollow cathode cavities surrounding the gas passages, wherein each of the hollow cathode cavities comprise a groove and a size of the grooves increases from the center region to the edge regions of the plate. The method further includes dissociating the deposition gas between the diffuser and the substrate support, and forming a film over the substrate from the dissociated gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic cross-section view of one embodiment of a vacuum chamber.

FIG. 1B is an enlarged cross-sectional view of the diffuser of FIG. 1A having one embodiment of a groove pattern.

FIG. 2 is a cross-sectional view of a diffuser that may be used as the diffuser of FIG. 1A with another embodiment of a groove pattern.

FIGS. 3A-3C depict various views of a diffuser with another embodiment of a groove pattern that may be used as the diffuser of FIG. 1A.

FIGS. 4A-4C depict various views of a diffuser with another embodiment of a groove pattern that may be used as the diffuser of FIG. 1A.

FIGS. 5A-5C depict various views of a diffuser with another embodiment of a groove pattern that may be used as the diffuser of FIG. 1A.

FIGS. 6A-6C depict various views of a diffuser with another embodiment of a groove pattern that may be used as the diffuser of FIG. 1A.

FIGS. 7A-7C depict various views of a diffuser with another embodiment of a groove pattern that may be used as the diffuser of FIG. 1A.

FIGS. 8A-8C depict various views of a diffuser with another embodiment of a groove pattern that may be used as the diffuser of FIG. 1A.

FIG. 9 is a side cross-sectional view of various groove profiles that may be formed in any one of the diffusers as described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure generally relate to a gas diffuser designed to ensure substantially uniform deposition on a substrate. The gas diffuser can compensate for plasma non-uniformities in the corner regions thereof. The gas diffuser can be modified according to embodiments described herein to tune plasma parameters to ensure control of plasma formation across the surface area of the gas diffuser.

Embodiments herein are illustratively described below in reference to a PECVD system configured to process large area substrates, such as a PECVD system, available from AKT, a division of Applied Materials, Inc., Santa Clara, Calif. However, it should be understood that the disclosure has utility in other system configurations such as etch systems, other chemical vapor deposition systems, physical vapor deposition systems, and any other system in which distributing gas within a process chamber is desired, including those systems configured to process round substrates.

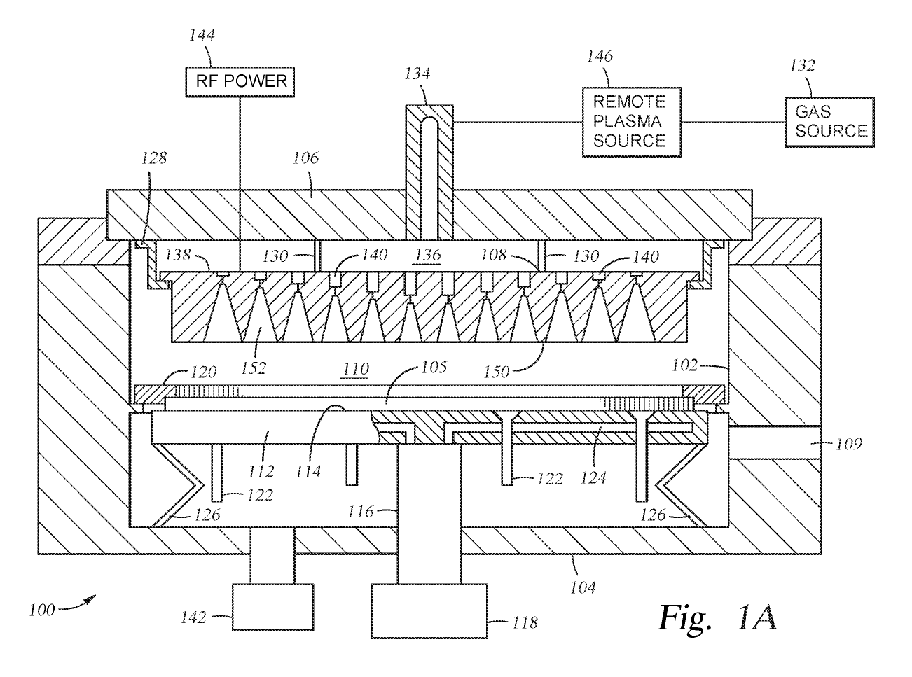

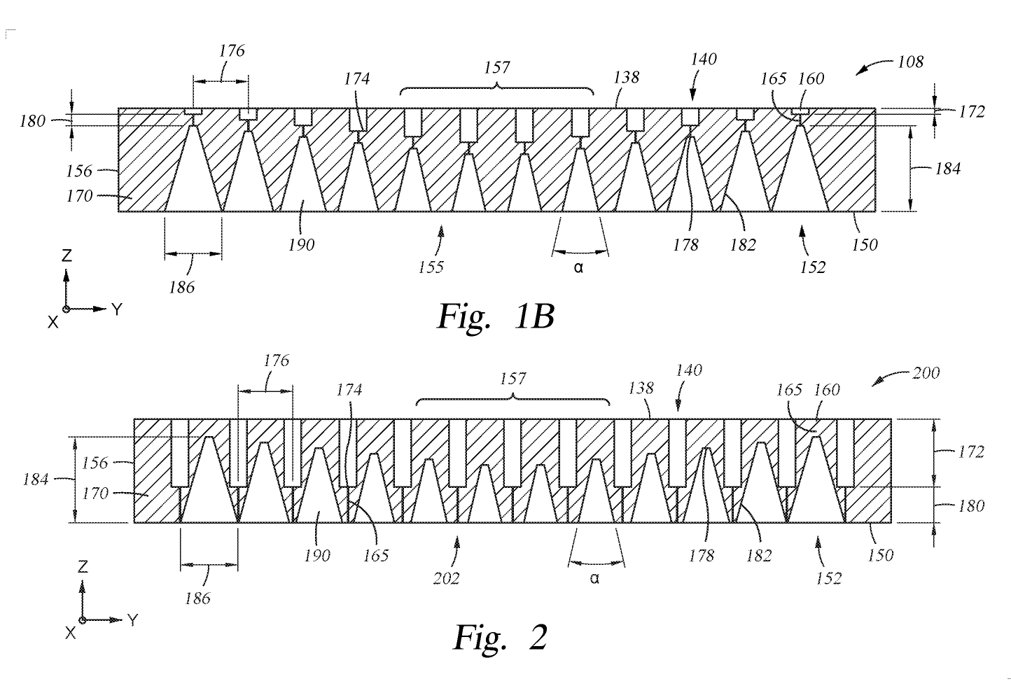

FIG. 1A is a schematic cross-section view of one embodiment of a vacuum chamber 100 for forming electronic devices, such as thin film transistors (TFTs) and active matrix organic light emitting diodes (AMOLEDs) for forming flat panel displays by a PECVD process. It is noted that FIG. 1A is just an exemplary apparatus that may be used to form electronic devices on a substrate. One suitable chamber for a PECVD process is available from Applied Materials, Inc., located in Santa Clara, Calif. It is contemplated that other deposition chambers, including those from other manufacturers, may be utilized to practice the embodiments of the disclosure.

The vacuum chamber 100 generally includes walls 102, a bottom 104, and a backing plate 106, which collectively define a process volume 110. A sealable slit valve 109 is formed through the walls 102 such that a substrate 105 may be transferred into and out of the vacuum chamber 100. Positioned within the process volume 110 is a substrate support 112 that opposes a gas distribution plate or diffuser 108. The diffuser 108 functions as an electrode during a deposition process in the vacuum chamber 100. The substrate support 112 includes a substrate receiving surface 114 for supporting the substrate 105 and a stem 116 is coupled to a lift system 118 to raise and lower the substrate support 112. A shadow frame 120 may be placed over periphery of the substrate 105 during processing. Lift pins 122 are moveably disposed through the substrate support 112 to move the substrate 105 toward and away from the substrate receiving surface 114 in a substrate transfer process. The substrate support 112 may also include heating and/or cooling elements 124 to maintain the substrate support 112 and substrate 105 positioned thereon at a desired temperature. The substrate support 112 may also include grounding straps 126 to provide RF grounding at the periphery of the substrate support 112.

The diffuser 108 is coupled to the backing plate 106 at its periphery by a suspension 128. The diffuser 108 may also be coupled to the backing plate 106 by one or more support members 130 to help prevent sag and/or control the straightness of the diffuser 108. A gas source 132 is coupled to a process fluid port 134 disposed through the backing plate 106 that provides fluids to a space 136 formed between the backing plate 106 and a first major surface 138 of the diffuser 108. The fluids pass through the space 136 to a plurality of gas passages 140 formed in the diffuser 108 and to the process volume 110 where a thin film is formed on the substrate 105. The fluids from the process fluid port 134 may be a gas or gases in a molecular state, or a gas or gases in an excited state, for example an ionic and/or dissociated state.

A vacuum pump 142 is coupled to the vacuum chamber 100 to control the pressure within the process volume 110. A radio frequency (RF) power source 144 is coupled to the backing plate 106 and/or to the diffuser 108 to provide RF power to the diffuser 108. The RF power is utilized to generate an electric field between the diffuser 108 and the substrate support 112 such that a plasma may be formed from the gases present between the diffuser 108 and the substrate support 112. In some embodiments, the plasma may be used to maintain excitation of gases between the diffuser 108 and the substrate support 112. Various RF frequencies may be used, such as a frequency between about 0.3 MHz and about 200 MHz. In one embodiment, the RF power source 144 provides power to the diffuser 108 at a frequency of 13.56 MHz.

A remote plasma source 146, such as an inductively coupled remote plasma source, may also be coupled between the gas source 132 and the backing plate 106. Gases may be excited into a plasma prior to entering the process volume 110 and is flowed through the diffuser 108 in a manner similar to the flow described above. In some embodiments, the remote plasma source 146 may be utilized between processing substrates. For example, a cleaning gas may be provided to the remote plasma source 146 and excited to form a remote plasma from which dissociated cleaning gas species are generated and provided to clean chamber components. The cleaning gas may be maintained or further excited by the RF power source 144 and to reduce recombination of the dissociated cleaning gas species. Suitable cleaning gases include but are not limited to nitrogen trifluoride (NF₃), fluoride (F₂) and sulfur hexafluoride (SF₆).

In one embodiment, the heating and/or cooling elements 124 may be utilized to maintain the temperature of the substrate support 112 and substrate 105 thereon during deposition at about 400 degrees Celsius, or less. In one embodiment, the heating and/or cooling elements 124 may be used to control the substrate temperature to less than 100 degrees Celsius, such as between about 20 degrees Celsius and about 90 degrees Celsius. The spacing between a top surface of the substrate 105 disposed on the substrate receiving surface 114 and a second major surface 150 of the diffuser 108 may be between 400 mil (0.001 inches) and about 1,200 mil, for example between 400 mil and about 800 mil, during deposition.

In conventional diffusers, the openings formed therein (e.g., gas passages 140) may number in the thousands up to tens of thousands. The openings are typically formed by multiple drilling operations since hole sizes of each opening may vary. For example, each opening may include three or more diameters, which require three or more drill sizes to form each opening. Even in an automated machining operation the drill process takes considerable time. Additionally, many conventional diffusers have one or more major surfaces that are non-planar, e.g., concave or convex surfaces, which may be utilized to vary plasma density at least on the side of the diffuser facing the substrate. To form the non-planar surface, additional machining time and costs are incurred.

The diffuser 108 as described herein reduces machining time considerably as compared to conventional diffusers while maintaining or enhancing gas distribution and/or plasma parameters. In the embodiment shown in FIG. 1A, the first major surface 138 and the second major surface 150 are substantially parallel. In addition, the gas passages 140 comprise multiple grooves 152 that open at the second major surface 150. The gas passages 140 may comprise hollow cathode cavities and the grooves 152 may be used to provide a hollow cathode effect between the second major surface 150 and the substrate 105. The grooves 152 include different sizes (e.g., dimensions and/or depths) across the length and/or width of the second major surface 150. The sizes of the grooves 152 may also vary along a radial direction, an azimuthal direction and/or diagonally across the second major surface 150. For example, the sizes of the grooves 152 may increase from a center to edges of the second major surface 150. In addition, the sizes (e.g., dimensions (diameters) and/or depths) of other portions of the gas passages 140 may vary across the first major surface 138.

FIG. 1B is an enlarged cross-sectional view of the diffuser 108 of FIG. 1A having one embodiment of a groove pattern 155. The diffuser 108 includes a plate 170 that is fabricated from a metallic material, such as aluminum, or other conductive material. The thickness of the plate 170 may be about 0.8 inch to about 3.0 inches, for example, about 0.8 inch to about 2.0 inch. The plate 170 includes the first major surface 138 (e.g., an upstream side) and the second major surface 150 (e.g., a downstream side) as well as edges 156 and a center region 157. In some embodiments, the plate 170 is rectangular and includes four edges 156.

According to this embodiment of the groove pattern 155, each gas passage 140 is defined by an upstream bore 160 coupled by a second bore or orifice hole 165 to the groove 152 that combine to form a fluid path through the plate 170 of the diffuser 108. The upstream bore 160 extends a depth 172 from the first major surface 138 (e.g., an upstream side) of the diffuser 108 to a bottom 174. The bottom 174 of the upstream bore 160 may be square, tapered, beveled, chamfered or rounded to minimize the flow restriction as fluids flow from the upstream bore 160 into the orifice hole 165. The upstream bore 160 generally has a diameter of about 0.093 to about 0.174 inches, and in one embodiment is about 0.156 inches. The diameters may be the same or different between all of the gas passages 140. A pitch 176 between the gas passages 140 may be about 0.3 inches. The pitch 176 may be the same or different between all of the gas passages 140. In some embodiments, the pitch 176 may be substantially equal in one or any combination of the X direction, the Y direction, and diagonally.

The orifice hole 165 generally couples the bottom 174 of the upstream bore 160 and a bottom 178 of the groove 152. The orifice hole 165 may include a diameter of about 0.01 inch to about 0.3 inch, for example, about 0.01 inch to about 0.1 inch, and may include a length 180 (or second depth) of about 0.02 inch to about 1.0 inch, for example, about 0.02 inch to about 0.5 inch. The orifice hole 165 may be a choke hole and the length 180 and diameter (or other geometric attribute) of the orifice hole 165 is the primary source of back pressure in the space 136 between the diffuser 108 and the backing plate 106 (shown in FIG. 1A) which promotes even distribution of gas across the first major surface 138 of the diffuser 108. The orifice hole 165 is typically configured uniformly among the plurality of gas passages 140; however, the restriction through the orifice hole 165 may be configured differently among the gas passages 140 to promote more gas flow through one area or region of the diffuser 108 relative to another area or region. For example, the orifice hole 165 may have a larger diameter and/or a shorter length 180 in those gas passages 140, of the diffuser 108, closer to the wall 102 (shown in FIG. 1A) of the vacuum chamber 100 so that more gas flows through the edges of the diffuser 108 to increase the deposition rate at portions of the perimeter areas of the substrate 105. In some embodiments, the depths 172 if the upstream bores 160 vary across the first major surface 138 while the lengths 180 of the orifice holes 165 are substantially equal. However, in other embodiments, the depths 172 of the upstream bores 160 may be substantially equal while the lengths 180 of the orifice holes 165 vary. In one embodiment, the depth 172 of the upstream bores 160 decreases from a center region 157 of the diffuser 108 to the edges 156 of the diffuser 108.

Each of the grooves 152 have two opposing sidewalls 182 that extend from the orifice hole 165 to the second major surface 150 (e.g., a downstream side) of the diffuser 108. The sidewalls 182 may converge at an opening formed by the orifice hole 165, or at the bottom 178 of the groove 152. The bottom 178 may be flat, tapered or rounded similar to the bottom 174 of the upstream bores 160. Each of the grooves 152 may include an angle α between the sidewalls 182 of about 10 degrees to about 50 degrees, such as about 18 degrees to about 25 degrees, for example, about 22 degrees. The grooves 152 may be formed in the diffuser 108 at a depth 184 of about 0.10 inch to about 2.0 inches. The depth may vary within or along a single groove 152 or may vary from groove to groove. In one embodiment, the depth 184 may be about 0.1 inch to about 1.0 inch. A maximum dimension or length 186 of at least a portion of the grooves 152 may be about 0.3 inches, or less. In some embodiments, each of the grooves 152 include the same angle α but the length 186 and/or the depth 184 varies across the second major surface 150 of the diffuser 108. Additionally or alternatively, the width of the bottom 178 of the groove 152 may vary within or along a single groove 152 or may vary from groove to groove. In some embodiments, the angle α may vary within or along a single groove 152 or may vary from groove to groove.

In one embodiment, the space between the sidewalls 182 of each of the grooves 152 comprises hollow cathode cavities 190. For example, the orifice holes 165 generate a back pressure on the first major surface 138 of the diffuser 108. Due to the back pressure, process gases may evenly distribute on the first major surface 138 of the diffuser 108 before passing through the gas passages 140. The spaces of the hollow cathode cavities 190 permit a plasma to be generated within the gas passages 140, specifically within the sidewalls 182 of each of the grooves 152. Additionally, plasma may be produced at the second major surface 150 and also the process volume 110 (shown in FIG. 1A) as well as within the hollow cathode cavities 190. The variations of the space of the hollow cathode cavities 190 permit greater control of plasma distribution as opposed to the situation where no hollow cathode cavities are present. Further, the plasma formed in locations near the hollow cathode cavities 190 may be denser as compared to locations where no hollow cathode cavities are present. At least a portion of the hollow cathode cavities 190 at the second major surface 150 may have a greater length 186 or depth 184 than the orifice holes 165. The upstream bore 160 has a width or diameter less than the plasma dark space and thus, plasma is not formed above the hollow cathode cavities 190. The space (e.g., the length 186 and depth 184) of the hollow cathode cavities 190 may vary across the second major surface 150 of the diffuser 108. For example, an increase in one or both of the length 186 and depth 184 increases plasma density. In one embodiment, the space of the hollow cathode cavities 190 increases from a center region 157 of the diffuser 108 to the edges 156 of the diffuser 108, which may provide more plasma density at the edges 156 of the diffuser 108 as compared to a plasma density at the center region 157 of the diffuser 108. The length 186 and/or the depth 184 of the hollow cathode cavities 190 may be varied during manufacture of the diffuser 108 and provides enhancement and/or stabilization of plasma parameters locally, and provide a hollow cathode gradient across the diffuser 108. The variations in length 186, width, and/or depth 184 may compensate for or reduce standing wave effects as well as electrode edge effects, which provides more uniform deposition of films on a substrate. The hollow cathode gradient may be center to edge, edge to center, center to corners, radially, or diagonally.

FIG. 2 is a cross-sectional view of a diffuser 200 that may be used as the diffuser 108 of FIG. 1A with another embodiment of a groove pattern 202. The groove pattern 202 differs from the groove pattern 155 of the diffuser 108 in that the grooves 152 are offset from the gas passages 140. Thus, the gas passages 140 comprise the upstream bores 160 and the corresponding orifice holes 165 provide a flow path through the plate 170. In addition, the depth 172 of the upstream bores 160, and the length 180 of the orifice holes 165, are substantially equal. In this embodiment, the hollow cathode cavities 190 may locally increase plasma density based on the size of the grooves 152.

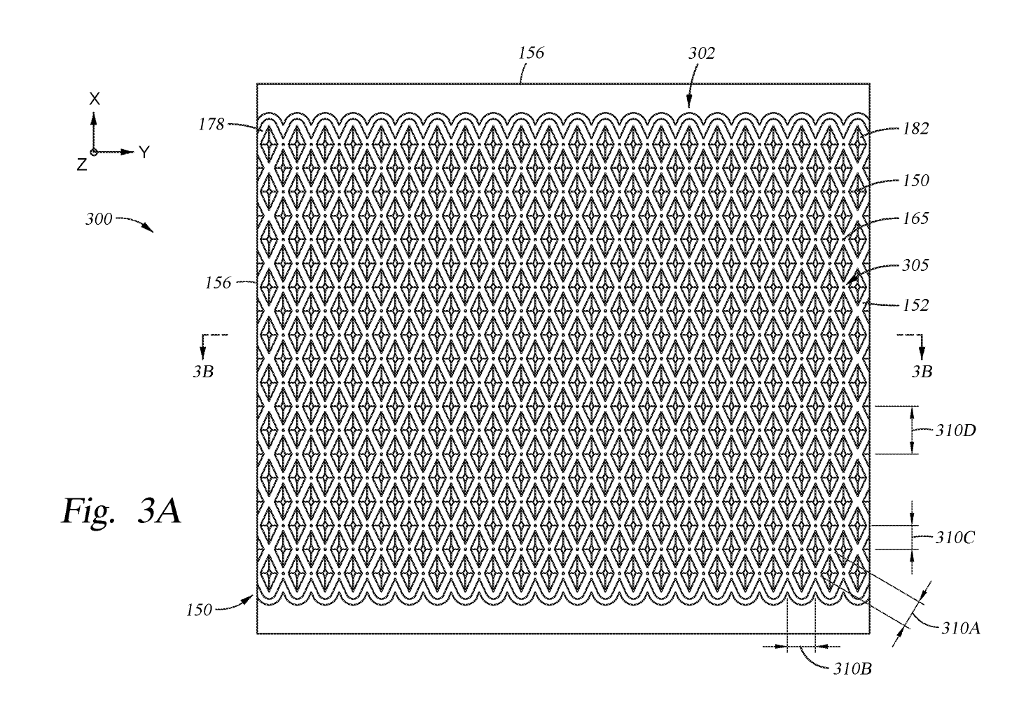

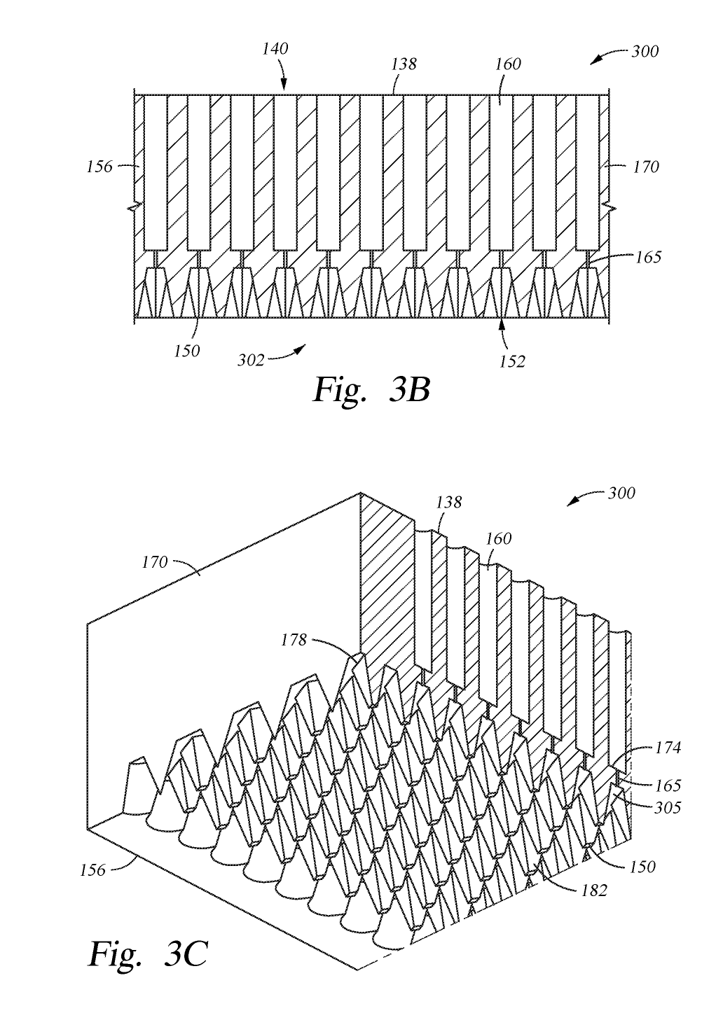

FIGS. 3A-3C are various views of a diffuser 300 with another embodiment of a groove pattern 302 that may be used as the diffuser 108 of FIG. 1A. FIG. 3A is a bottom plan view of the diffuser 300. FIG. 3B is a partial side cross-sectional view of the diffuser 300 of FIG. 3A. FIG. 3C is a partial isometric cross-sectional view of the diffuser 300 of FIG. 3A.

The groove pattern 302 depicted on the diffuser 300 may be a diagonal pattern wherein at least a portion of the grooves 152 intersect with other grooves 152. Intersections 305 are formed where the grooves 152 connect and an orifice hole 165 may be formed in a portion of the intersections 305, in one embodiment (similar to the groove pattern 155 shown and described in FIG. 1B). However, in other embodiments, the groove pattern 202 shown and described in FIG. 2 may replace the groove pattern 302 of the diffuser 300. The orifice holes 165 may align in one or all of the X direction, the Y direction and diagonally, or may be offset in one or more of the directions, as shown. While not shown in FIG. 3B, the depth and/or width of the grooves 152, as well as dimensions of the orifice holes 165 and upstream bores 160, may vary across the length of the diffuser 300 similar to the embodiments of the diffusers 108 and 200 shown and described in FIGS. 1B and 2, respectively.

In some embodiments, a pitch (shown as 310A, 310B and 310C) between adjacent orifice holes 165 may be different or substantially equal across the second major surface 150 of the diffuser 300. In one embodiment, the pitch 310A (diagonally) and the pitch 310B (X direction) may be substantially equal while the pitch 310C (Y direction) is slightly less than the pitches 310A and 310B. In some embodiments, the density of orifice holes 165 is substantially equal across the second major surface 150 of the diffuser 700 at least in a radial direction. Substantially equal may be defined in this context as within +/−0.03 inches, or less. Additionally or alternatively, a pitch 310D of alternating orifice holes 165 (in the X direction) may be greater than all of the pitches 310A, 310B and 310C. In some embodiments, the pitches 310A, 310B, 310C and 310D remain constant across the second major surface 150 of the diffuser 300.

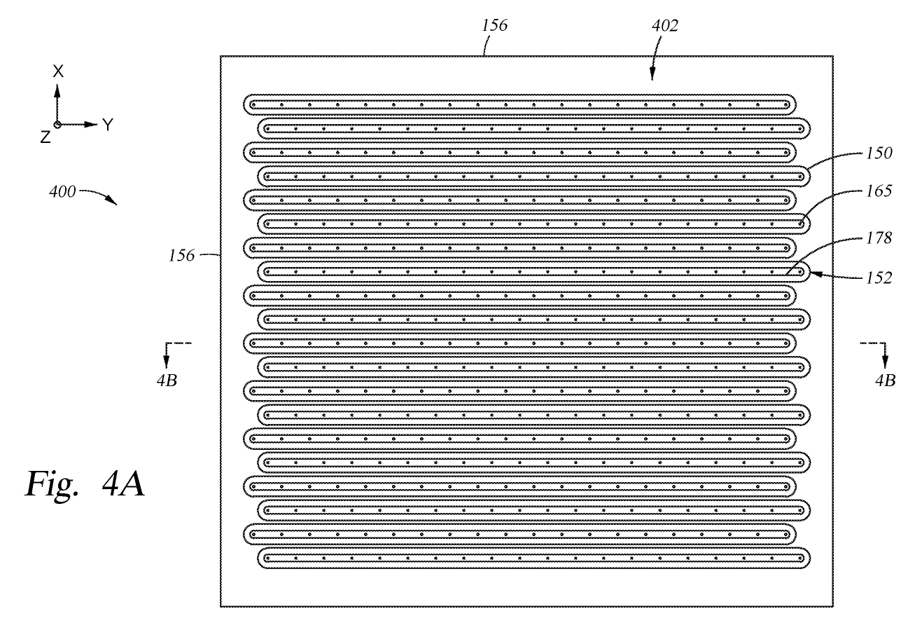

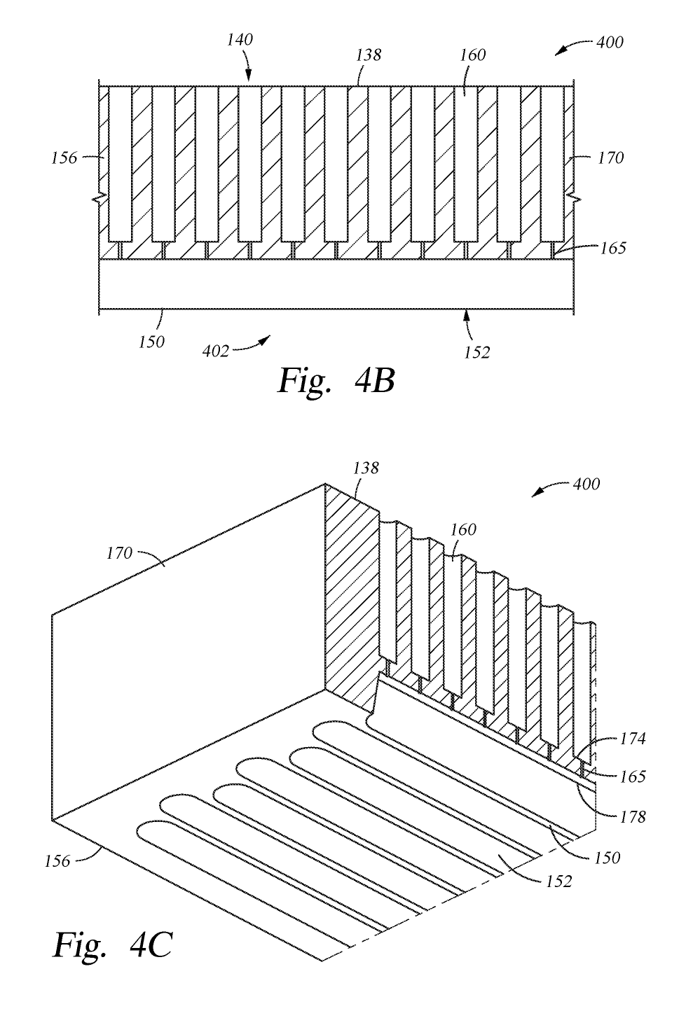

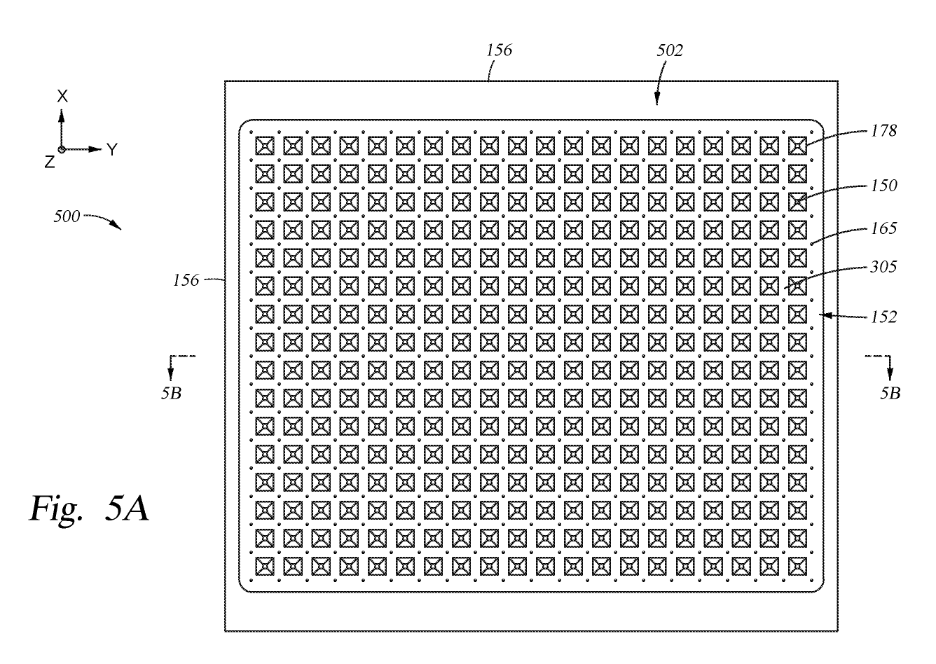

FIGS. 4A-4C are various views of a diffuser 400 with another embodiment of a groove pattern 402 that may be used as the diffuser 108 of FIG. 1A. FIG. 4A is a bottom plan view of the diffuser 400. FIG. 4B is a partial side cross-sectional view of the diffuser 400 of FIG. 4A. FIG. 4C is a partial isometric cross-sectional view of the diffuser 400 of FIG. 4A.

The groove pattern 402 depicted on the diffuser 400 may be a linear pattern wherein the grooves 152 may be substantially parallel but offset in at least one direction. Orifice holes 165 may be formed in a bottom 178 of the grooves 152, in one embodiment (similar to the groove pattern 155 shown and described in FIG. 1B). However, in other embodiments, the groove pattern 202 shown and described in FIG. 2 may replace the groove pattern 402 of the diffuser 400. The orifice holes 165 may align in one or all of the X direction, the Y direction and diagonally, or may be offset in one or more of the directions, as shown. While not shown, pitches between the orifice holes 165, similar to the pitches 310A, 310B, 310C and 310D of FIG. 3A, may be the same or different across the second major surface 150 of the diffuser 400. In some embodiments, the density of orifice holes 165 is substantially equal across the second major surface 150 of the diffuser 400 at least in a radial direction. Additionally, while not shown in FIG. 4B, the depth and/or width of the grooves 152, as well as dimensions of the orifice holes 165 and upstream bores 160, may vary across the length of the diffuser 400 similar to the embodiments of the diffusers 108 and 200 shown and described in FIGS. 1B and 2, respectively.

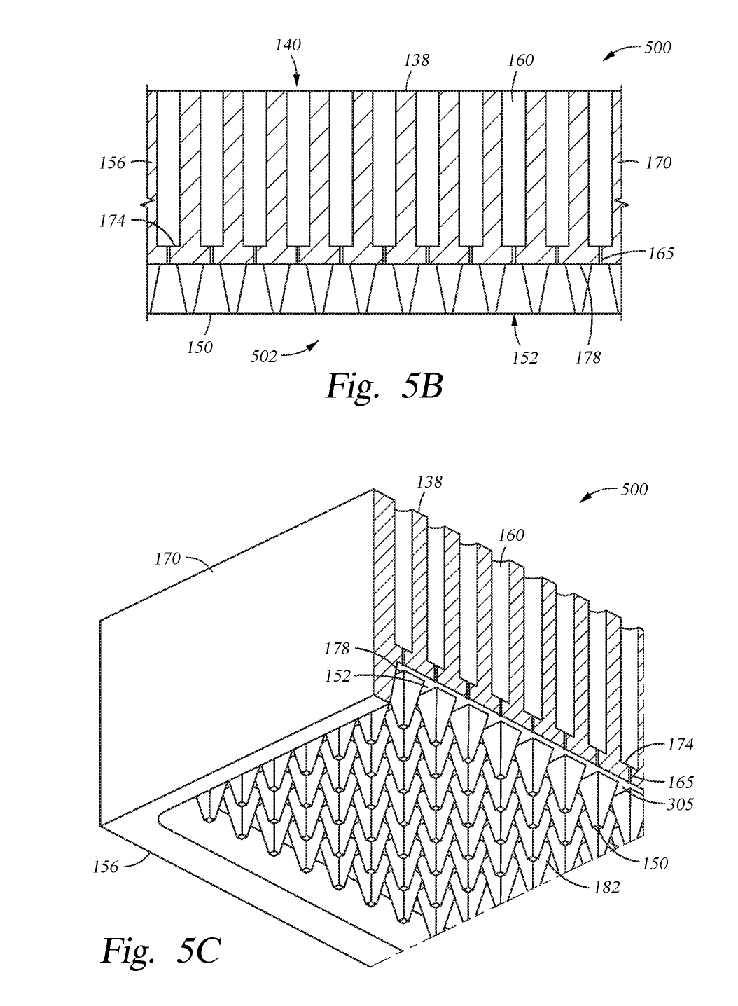

FIGS. 5A-5C are various views of a diffuser 500 with another embodiment of a groove pattern 502 that may be used as the diffuser 108 of FIG. 1A. FIG. 5A is a bottom plan view of the diffuser 500. FIG. 5B is a partial side cross-sectional view of the diffuser 500 of FIG. 5A. FIG. 5C is a partial isometric cross-sectional view of the diffuser 500 of FIG. 5A.

The groove pattern 502 depicted on the diffuser 500 may be an array or array-like pattern wherein the grooves 152 may be substantially parallel in two orthogonal directions that form intersections 305 where the grooves 152 cross. Orifice holes 165 may be formed in a bottom 178 of the grooves 152 at the intersections 305, in one embodiment (similar to the groove pattern 155 shown and described in FIG. 1B). However, in other embodiments, the groove pattern 202 shown and described in FIG. 2 may replace the groove pattern 502 of the diffuser 500. The orifice holes 165 may align in one or all of the X direction, the Y direction and diagonally, as shown, or may be offset in one or more of the directions. While not shown, pitches between the orifice holes 165, similar to the pitches 310A, 310B, 310C and 310D of FIG. 3A, may be the same or different across the second major surface 150 of the diffuser 500. In some embodiments, the density of orifice holes 165 is substantially equal across the second major surface 150 of the diffuser 500 at least in a radial direction. Additionally, while not shown in FIG. 5B, the depth and/or width of the grooves 152, as well as dimensions of the orifice holes 165 and upstream bores 160, may vary across the length of the diffuser 500 similar to the embodiments of the diffusers 108 and 200 shown and described in FIGS. 1B and 2, respectively.

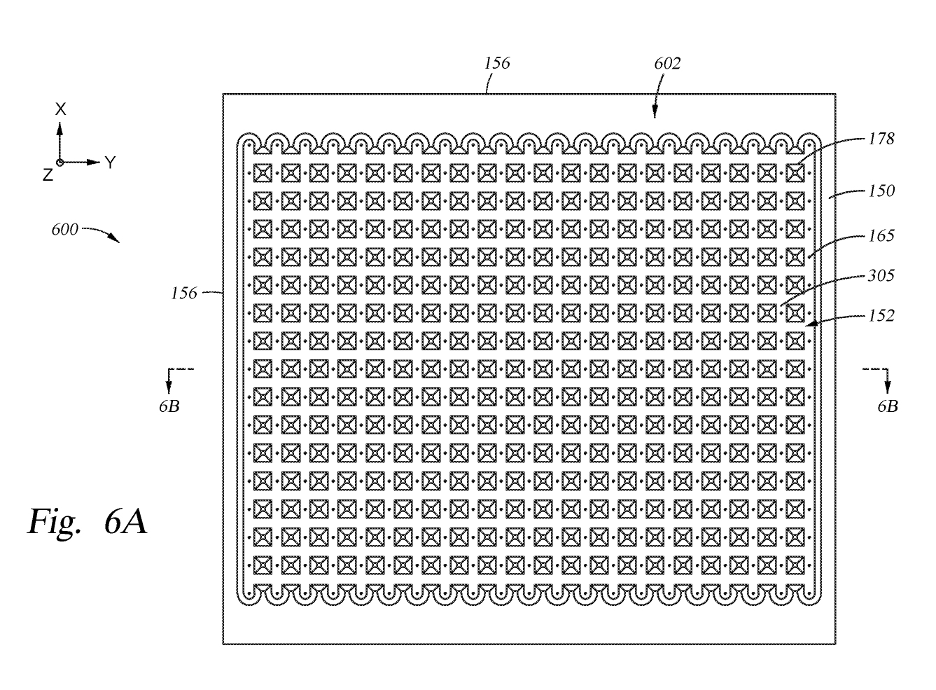

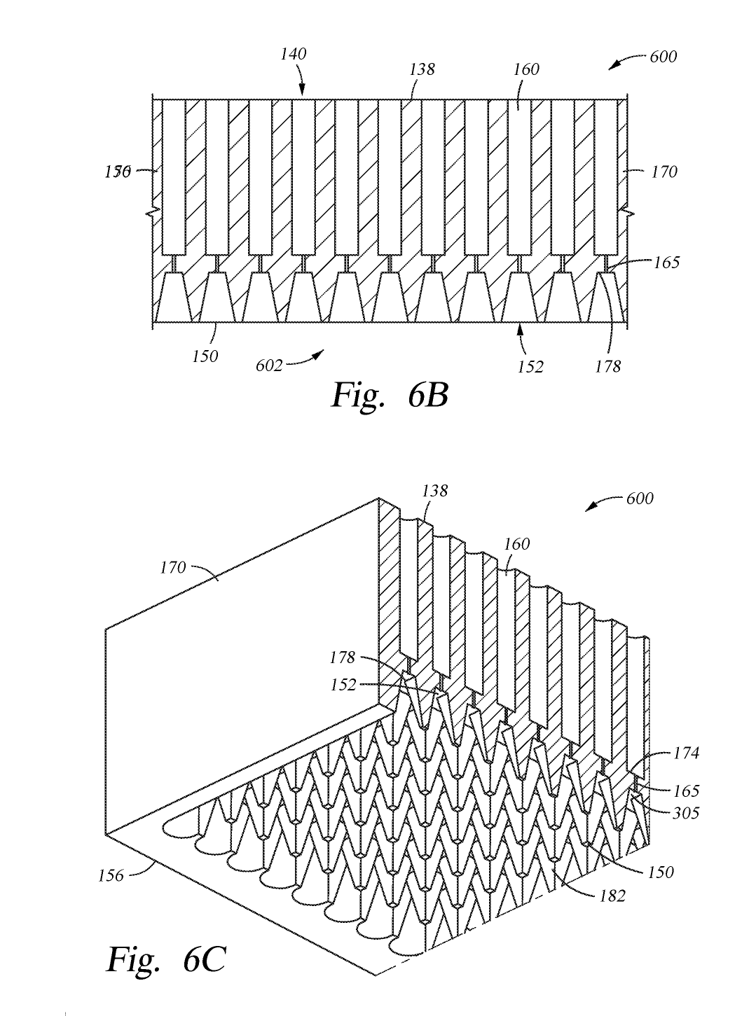

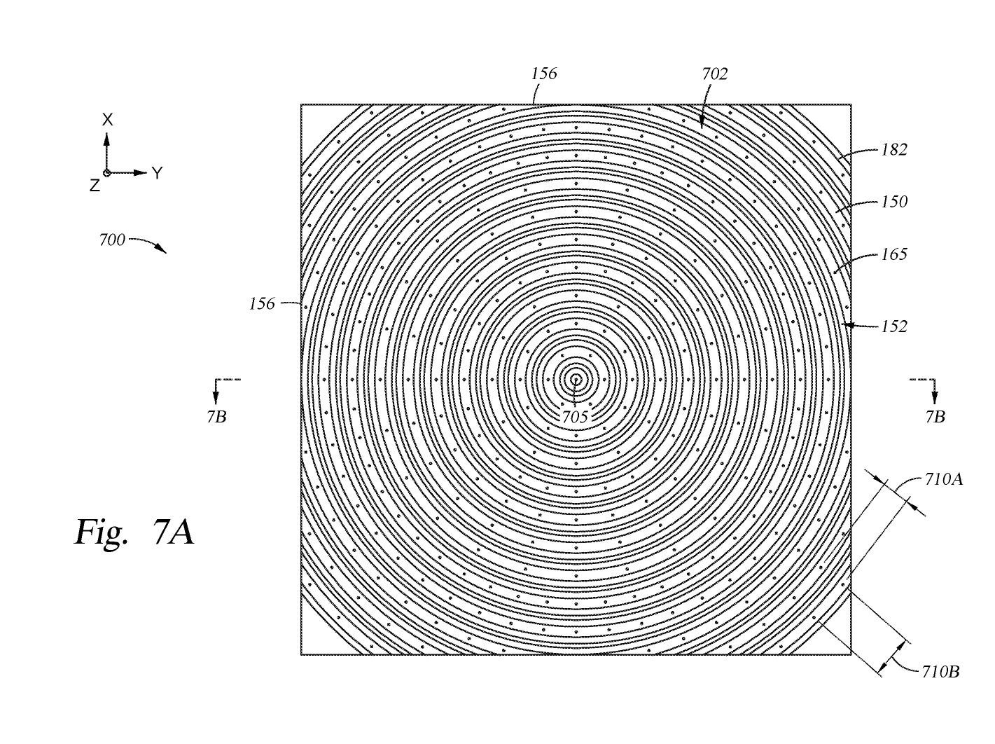

FIGS. 6A-6C are various views of a diffuser 600 with another embodiment of a groove pattern 602 that may be used as the diffuser 108 of FIG. 1A. FIG. 6A is a bottom plan view of the diffuser 600. FIG. 6B is a partial side cross-sectional view of the diffuser 600 of FIG. 6A. FIG. 6C is a partial isometric cross-sectional view of the diffuser 600 of FIG. 6A.

The groove pattern 602 depicted on the diffuser 600 may be an offset array or offset array-like pattern wherein the grooves 152 may be substantially parallel but offset in at least one direction. Orifice holes 165 may be formed in a bottom 178 of the grooves 152 at the intersections 305, in one embodiment (similar to the groove pattern 155 shown and described in FIG. 1B). However, in other embodiments, the groove pattern 202 shown and described in FIG. 2 may replace the groove pattern 602 of the diffuser 600. The orifice holes 165 may align in one or all of the X direction, the Y direction and diagonally, or may be offset in one or more of the directions, as shown. While not shown, pitches between the orifice holes 165, similar to the pitches 310A, 310B, 310C and 310D of FIG. 3A, may be the same or different across the second major surface 150 of the diffuser 600. In some embodiments, the density of orifice holes 165 is substantially equal across the second major surface 150 of the diffuser 600 at least in a radial direction. Additionally, while not shown in FIG. 6B, the depth and/or width of the grooves 152, as well as dimensions of the orifice holes 165 and upstream bores 160, may vary across the length of the diffuser 600 similar to the embodiments of the diffusers 108 and 200 shown and described in FIGS. 1B and 2, respectively.

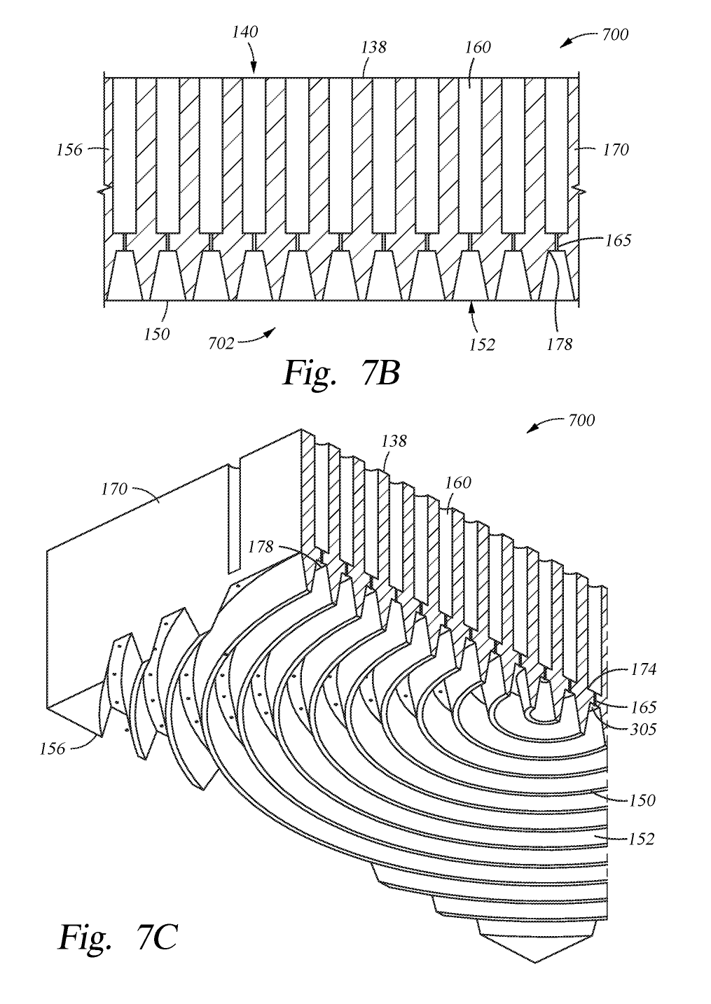

FIGS. 7A-7C are various views of a diffuser 700 with another embodiment of a groove pattern 702 that may be used as the diffuser 108 of FIG. 1A. FIG. 7A is a bottom plan view of the diffuser 700. FIG. 7B is a partial side cross-sectional view of the diffuser 700 of FIG. 7A. FIG. 7C is a partial isometric cross-sectional view of the diffuser 700 of FIG. 7A.

The groove pattern 702 depicted on the diffuser 700 may be a circular or a concentric ring pattern wherein the grooves 152 may be substantial circles. Orifice holes 165 may be formed in a bottom 178 of the grooves 152, in one embodiment (similar to the groove pattern 155 shown and described in FIG. 1B). However, in other embodiments, the groove pattern 202 shown and described in FIG. 2 may replace the groove pattern 702 of the diffuser 700. The orifice holes 165 may align linearly in a radial direction from a center gas passage 705, or may be offset in a radial direction. Pitches 710A and 710B of the orifice holes 165 may be the same or different across the second major surface 150 of the diffuser 700. In some embodiments, the density of orifice holes 165 is substantially equal across the second major surface 150 of the diffuser 700 at least in a radial direction. While not shown in FIG. 7B, the depth and/or width of the grooves 152, as well as dimensions of the orifice holes 165 and upstream bores 160, may vary across the length of the diffuser 700 similar to the embodiments of the diffusers 108 and 200 shown and described in FIGS. 1B and 2, respectively. Although the diffuser 700 has a groove pattern 702 that is substantially circular, the groove pattern may also be oval-shaped grooves that may be concentric. In one example, an alternative groove pattern may be elliptical grooves that may be concentric.

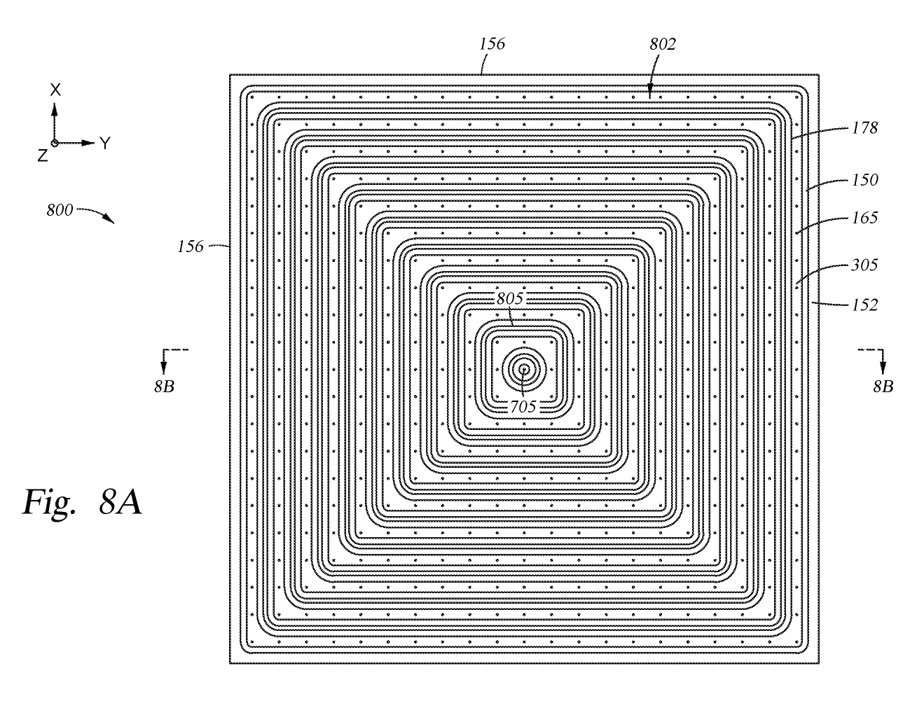

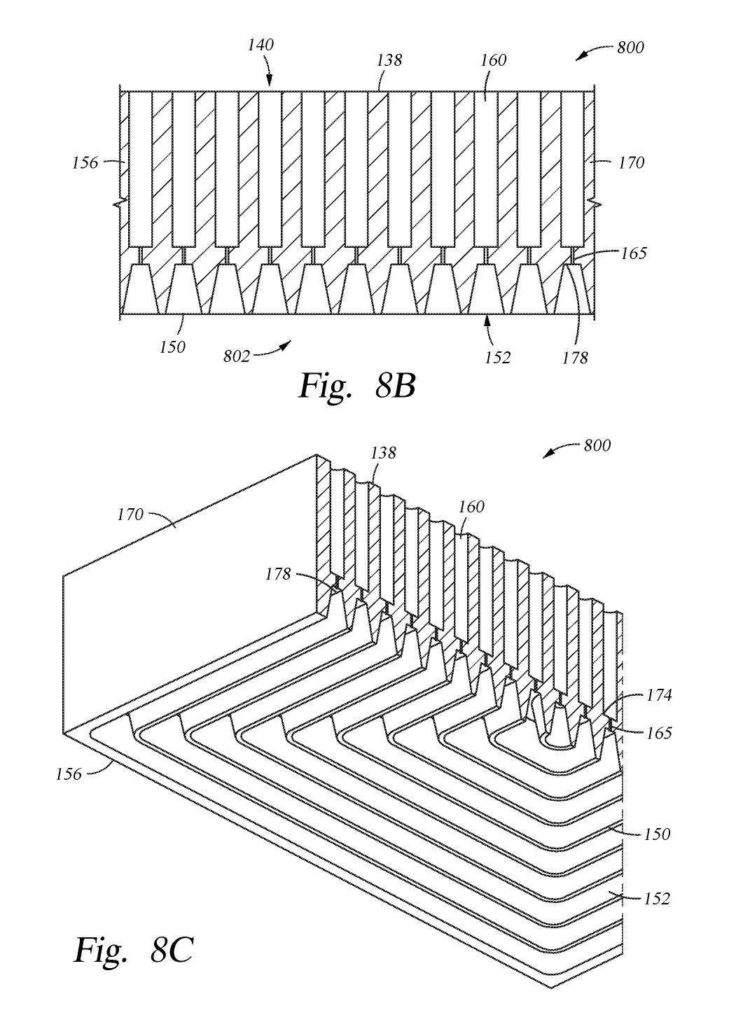

FIGS. 8A-8C are various views of a diffuser 800 with another embodiment of a groove pattern 802 that may be used as the diffuser 108 of FIG. 1A. FIG. 8A is a bottom plan view of the diffuser 800. FIG. 8B is a partial side cross-sectional view of the diffuser 800 of FIG. 8A. FIG. 8C is a partial isometric cross-sectional view of the diffuser 800 of FIG. 8A.

The groove pattern 802 depicted on the diffuser 800 may be a rectangular pattern wherein a portion of the grooves 152 may be substantially parallel. In some embodiments, a central groove 805 may be included in the groove pattern 802. Orifice holes 165 may be formed in a bottom 178 of the grooves 152, in one embodiment (similar to the groove pattern 155 shown and described in FIG. 1B). However, in other embodiments, the groove pattern 202 shown and described in FIG. 2 may replace the groove pattern 802 of the diffuser 800. The orifice holes 165 may align linearly in a radial direction from a center gas passage 705, or may be offset in a radial direction. The orifice holes 165 may also align in one or all of the X direction, the Y direction and diagonally, or may be offset in one or more of the directions. While not shown, pitches between the orifice holes 165, similar to the pitches 710A and 710B of FIG. 7A, may be the same or different across the second major surface 150 of the diffuser 700. Additionally, while not shown in FIG. 7B, the depth and/or width of the grooves 152, as well as dimensions of the orifice holes 165 and upstream bores 160, may vary across the length of the diffuser 700 similar to the embodiments of the diffusers 108 and 200 shown and described in FIGS. 1B and 2, respectively. While not shown, an alternative groove pattern may be rectangular grooves mixed with circular or oval-shaped grooves. In one example, the groove pattern may comprise a plurality of parallel grooves connected on each end by a respective semicircular or arced groove resembling a concentric “race track” like pattern of grooves. In another example, the groove pattern may comprise concentric arc-shaped grooves each resembling a concentric “football” shaped pattern of grooves.

While not shown, a diffuser having a groove pattern with a plurality of radially oriented grooves formed in the second major surface 150 is contemplated. The groove pattern may resemble spokes on a wheel in one aspect. The radially oriented grooves may extend from a common point on the second major surface 150, such as a geometric center of the plate 170. In some embodiments, the radially oriented grooves have a depth and/or width that varies from the center to the edge of the plate 170. In other embodiments, the radially oriented grooves have a depth and/or width that increases from the center to the edge of the plate 170.

Other examples of a groove pattern on a diffuser include X/Y patterns, diagonal patterns, radial patterns, rectangular patterns, circular or oval patterns, spiral patterns, or combinations thereof. Among the various groove patterns disclosed herein, any one or combination of the groove patterns may include intersecting grooves or non-intersecting (separated) grooves, or combinations thereof. Among the various groove patterns disclosed herein, any one or combination of the groove patterns may include one or a plurality of grooves wherein the depth of the groove(s) is varied, the width of the groove(s) is varied, the pitch of the groove(s) is varied, or combinations thereof.

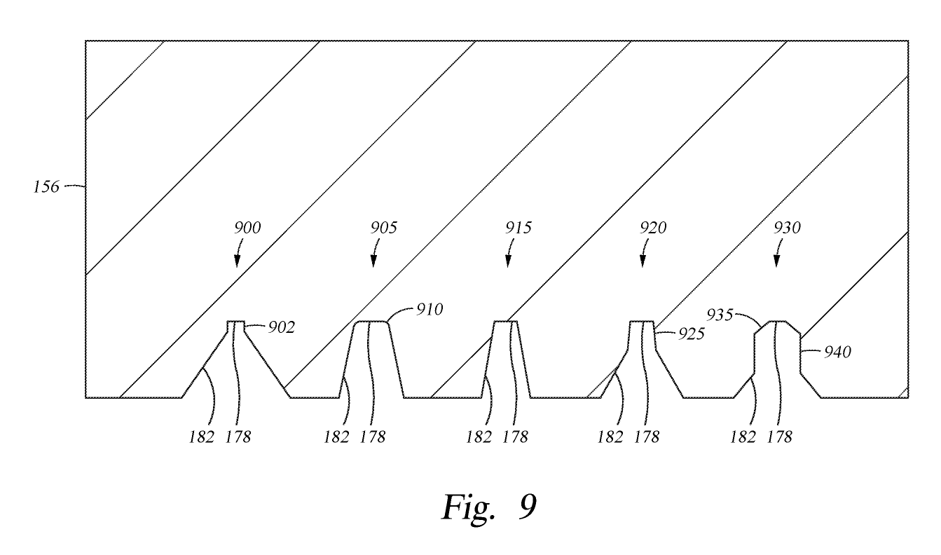

FIG. 9 is a side cross-sectional view of various groove profiles that may be formed in any one of the diffusers 108, 200, 300, 400, 500, 600, 700 and 800 as described herein.

Groove profile 900 includes a bottom 178 and angled sidewalls 182 connected by a radius 910.

Groove profile 915 includes a bottom 178 and angled sidewalls 182 similar to the embodiments of the grooves 152 described herein.

Groove profile 920 includes a bottom 178 and angled sidewalls 182 connected by an extended squared-wall 925. The extended squared-wall 925 may be substantially orthogonal to the bottom 178 and/or substantially parallel to a plane of the edge 156. The extended squared-wall 925 may have a length greater than the squared-wall 902 depicted in the groove profile 900.

Groove profile 930 includes a bottom 178 and angled sidewalls 182 connected by a tapered wall 935 and a central squared-wall 940. The central squared-wall 940 may be substantially orthogonal to a plane of the bottom 178 and/or substantially parallel to a plane of the edge 156. The tapered wall 935 may be formed at an angle that is substantially the same as the angled sidewalls 182, or a different angle.

The groove profiles 900, 905, 915, 920 and 930 as shown in FIG. 9 may be formed by an appropriately shaped end mill. Other profiles that are not shown may be formed based on a profile or shape of an end mill or other cutting tool.

Manufacture of a diffuser such as the diffusers 108, 200, 300, 400, 500, 600, 700 and 800 as described herein may be performed at a low cost as one drilling operation for forming thousands of holes is replaced by a milling process. The milling process can be performed in less time with reduced tool breakage as compared to a drilling operation.

Starting with a solid plate, an automated milling or drilling machine may be provided with a drill bit (or multiple drill bits, depending on the capability of the machine) of a desired size for formation of the orifice holes 165 and programmed to drill the orifice holes in a first side of the plate (e.g., the first major surface 138). For example, a computer numerical control (CNC) machine may be programmed to drill the orifice holes 165 in the first side of the plate, or entirely through the plate, at a predefined pitch.

Then, a second drill bit (or multiple drill bits, depending on the capability of the machine) of a certain size may be provided to the automated machine for formation of the upstream bores 160 in the first side. A drill bit for forming upstream bores having a diameter of about 0.093 inch to about 0.25 inch may be used. In one example, when forming upstream bores 160 with a diameter of about 0.1 inch, a 0.1 inch drill bit may be used and the machine is programmed to drill holes of a desired depth in each of the gas passages 140. The depth 172 (shown in FIGS. 1B and 2) of the upstream bores 160 may be the same or varied as described herein.

After each of the upstream bores 160 are formed, the plate may be flipped such that a second side (e.g., the second major surface 150) may be milled to form the grooves 152. An end mill (or multiple end mills, depending on the capability of the machine) of a desired size and/or profile may be provided to the automated machine for formation of the grooves 152 in the second side. An end mill for forming the grooves 152 having an angle α as described in FIGS. 1B and 2 may be used. The machine may be programmed to vary the depth 184 (shown in FIGS. 1B and 2) of the grooves 152. Varying the depth 184 of the grooves 152 may also vary the length 180 (shown in FIGS. 1B and 2) of the orifice holes 165.

Embodiments of the diffusers 108, 200, 300, 400, 500, 600, 700 and 800 having the grooves 152 as described herein may increase the gas flow and compensate for low deposition rates on corner regions and/or edge regions of substrates. Utilization of the grooves 152 as hollow cathode cavities 190 may enhance or stabilize plasma formation locally or across the second major surface 150, which may compensate for standing wave effects and/or minimize electrode edge effects. Thus, overall film thickness uniformity is improved. The diffusers 108, 200, 300, 400, 500, 600, 700 and 800 may be manufactured according the embodiments described herein or the grooves 152 as described herein may be added to an existing diffuser in a retrofit process.

While the foregoing is directed to embodiments of the present disclosure, other and further embodiments of the disclosure may be devised without departing from the basic scope thereof, and the scope thereof is determined by the claims that follow.

1. A diffuser for a deposition chamber, comprising:
a plate having edge regions and a center region, and plurality of gas passages comprising an upstream bore and an orifice hole fluidly coupled to the upstream bore that are formed between an upstream side and a downstream side of the plate, and a plurality of grooves surrounding the gas passages, wherein a depth of the grooves varies from the edge regions to the center region of the plate.

2. The diffuser of claim 1, wherein the depth of the grooves increases from the center region to the edge region of the plate.

3. The diffuser of claim 1, wherein a width of the grooves varies from the edge regions to the center region of the plate.

4. The diffuser of claim 1, wherein a portion of the orifice holes are fluidly coupled to one or more grooves of the plurality of grooves.

5. The diffuser of claim 1, wherein the plurality of gas passages comprise a groove pattern on the downstream side of the plate.

6. The diffuser of claim 5, wherein the groove pattern comprises grooves that are fluidly coupled to the orifice holes.

7. The diffuser of claim 5, wherein the groove pattern comprises diagonally oriented grooves that at least partially intersect.

8. The diffuser of claim 5, wherein the groove pattern comprises an oval or circular pattern of substantially concentric grooves.

9. The diffuser of claim 5, wherein the groove pattern comprises a rectangular pattern.

10. The diffuser of claim 5, wherein the groove pattern comprises a plurality of radially oriented grooves extending from a geometric center of the plate.

11. A diffuser for a deposition chamber, comprising:
a plate having edge regions and a center region, and plurality of gas passages comprising an upstream bore and an orifice hole fluidly coupled to the upstream bore that are formed between an upstream side and a downstream side of the plate, and a plurality of hollow cathode cavities surrounding the gas passages, wherein each of the hollow cathode cavities comprise a groove and a width of the grooves increases from the center region to the edge regions of the plate.

12. The diffuser of claim 11, wherein a depth of the grooves varies from the edge regions to the center region of the plate.

13. The diffuser of claim 11, wherein a portion of the orifice holes are fluidly coupled to one or more grooves.

14. The diffuser of claim 11, wherein the plurality of gas passages comprise a groove pattern on the downstream side of the plate.

15. The diffuser of claim 14, wherein the groove pattern comprises grooves that are fluidly coupled to the orifice holes.

16. The diffuser of claim 14, wherein the groove pattern comprises diagonally oriented grooves that at least partially intersect.

17. The diffuser of claim 14, wherein the groove pattern comprises an oval or circular pattern of substantially concentric grooves.

18. The diffuser of claim 14, wherein the groove pattern comprises a rectangular pattern.

19. The diffuser of claim 14, wherein the groove pattern comprises a plurality of radially oriented grooves extending from a geometric center of the plate.

20. An electrode for a deposition chamber, comprising:
a plate having edge regions and a center region, and plurality of gas passages comprising an upstream bore and an orifice hole fluidly coupled to the upstream bore that are formed between an upstream side and a downstream side of the plate, and a plurality of hollow cathode cavities formed in a groove pattern on a downstream side of the plate and surrounding the gas passages, wherein the groove pattern comprises a plurality of grooves having a size that varies from the center region to the edge regions of the plate.
